(19) United States
(12) Patent Application Publication
(10) Pub. No.: US 2026/0352175 A1
(43) Pub. Date: Nov. 5, 2026

(54) SYSTEMS AND METHODS FOR REDUCING EMI IN A BIDIRECTIONAL CHARGER BASED ON LAYOUT AND PACKAGING

(71) Applicant: Rivian IP Holdings, LLC, Irvine, CA (US)

(72) Inventors: Chunhui Liu, Irvine, CA (US); Puneeth Srikanta Murthy, Irvine, CA (US); Lixiang Wei, Irvine, CA (US); Adam John Emes, Los Angeles, CA (US); Aashiv Vij, Los Alamito, CA (US); Tapan Shirish Mhatre, Cerritos, CA (US); Heng Kang, Los Angeles, CA (US); Nicholas Athol Keeling, Irvine, CA (US)

(21) Appl. No.: 19/198,575

(22) Filed: May 5, 2025

(51) Int. Cl. H03H 7/01; H02J 7/02; H02M 3/335

(52) U.S. Cl. CPC H03H 7/0138; H02J 7/02; H02M 3/33584

(57) ABSTRACT

A system for bi-directional charging includes a filter circuit, a first power circuit, and a second power circuit. The filter circuit includes a filter having a nanocrystalline core material that is configured to reduce electromagnetic interference (EMI) between an AC bus and an AC system. The first power circuit includes a first plurality of switching devices and is configured to transfer power between the AC bus and a first DC bus. AC lines of the filter circuit may be coupled to the first power circuit using one or more terminals with standoffs. The second power circuit includes a second plurality of switching devices and is coupled to at least one transformer, and is configured to transfer power between the first DC bus and a second DC bus. The filter circuit, first power circuit, and second power circuit may each include one or more printed circuit board assemblies.

### INTRODUCTION

The present disclosure is directed to techniques for reducing electromagnetic interference in bidirectional chargers.

### SUMMARY

In some embodiments, the present disclosure is directed to an improved layout and packaging arrangement for a charger such as a bi-directional charger for managing power flow between an alternating current (AC) system and an electric vehicle, for example. In some embodiments, the charger includes a filter circuit having a nanocrystalline filter (e.g., an EMI filter having a nanocrystalline core material) configured to reduce electromagnetic interference (EMI) between an AC bus and an AC system. In some embodiments, the charger includes power circuits having a plurality of switching devices, such as MOSFETs, that are configured to transfer power between the AC bus and a first direct current (DC) bus (e.g., using a DC-AC converter), and another plurality of switching devices and at least one transformer that are configured to transfer power between the first DC bus and a second DC bus (e.g., a DC-DC converter). In some embodiments, the filter circuit and power circuits are arranged and configured to reduce EMI. For example, the power flow from the AC bus to a high-voltage DC bus may follow a U-shape to address differential mode EMI. In a further example, grounding terminations are arranged outside of the U-shaped loop to lessen EMI propagated to ground. The filter circuit and power circuits may interface using one or more standoffs having integrated conductors (e.g., rather than wires, to lessen inductance and thus impedance). In some embodiments, the filter circuit and power circuits include one or more printed circuit board assemblies (PCBAs), in which the high-voltage, low voltage control, and analog-to-digital converter (ADC) layers are separated. In some embodiments, one or more of the power circuits may include integrated shielding arranged over one or more transformers (e.g., of a DC-DC converter) to avoid the need for fasteners and other hardware, while maintaining shielding to reduce EMI.

In some embodiments, the present disclosure is directed to a system having a filter circuit, a first power circuit, and a second power circuit. In some embodiments, the filter circuit includes a filter having a nanocrystalline core material (e.g., a nanocrystalline filter) that is configured to reduce electromagnetic interference (EMI) between an AC bus and an AC system. In some embodiments, the first power circuit includes a first plurality of switching devices and is configured to transfer power between the AC bus and a first DC bus. For example, the filter circuit may be coupled to the first power circuit using one or more terminals with standoffs. In some embodiments, the second power circuit includes a second plurality of switching devices and is coupled to at least one transformer, and is configured to transfer power between the first DC bus and a second DC bus. For example, in some embodiments, the second DC bus is configured to be coupled to a battery of an electric vehicle, and the filter circuit, the first power circuit, and the second power circuit are configured to provide bi-directional power transfer between the AC system and the battery of the electrical vehicle. In a further example, the first DC bus operates at a first nominal voltage, and the second DC bus operates at a second nominal voltage greater than the first nominal voltage.

In some embodiments, a power flow from the filter circuit to the first power circuit, and from the first power circuit to the second power circuit forms a loop, and a plurality of ground terminals of the first and second power circuits are arranged outside of the loop. For example, in some embodiments, the filter circuit, the first power circuit, and the second power circuit are arranged within a region having a perimeter, the power flow forms a loop in the region, and the plurality of ground terminals are arranged between the loop and the perimeter. In some embodiments, the system includes an enclosure that defines the region and the perimeter, and the filter circuit, the first power circuit, and the second power circuit are arranged inside the enclosure. For example, in some embodiments, the filter circuit is arranged along a first side of the perimeter, the first power circuit is arranged along a second side of the perimeter adjacent the first side and behind the filter circuit along the first side, and the second power circuits is arranged along a third side of the perimeter, adjacent the first power circuit, and behind the filter circuit. The arrangement of the filter circuit, the first power circuit, and the second power circuit may reduce differential mode EMI caused by the power flow.

In some embodiments, the first power circuit includes a first plurality of switching devices, such as MOSFETs, that are configured to convert between the AC bus and the first DC bus. In some such embodiments, the filter circuit includes a ferrite filter arranged electrically between the nanocrystalline filter and the plurality of switches of the first power circuit and that is configured to reduce EMI in the AC bus arising from switching of the plurality of switches.

In some embodiments, the filter system, the first power circuit, and the second power circuit may each include one or more printed circuit board assemblies (PCBAs). For example, in some embodiments, the second power circuit includes a PCBA having a plurality of layers, and a layer of the plurality of layers includes an EMI shield aligned with the at least one transformer electrically coupled to the second power circuit. In a further example, the filter system may include a first PCBA, the first power circuit may include a second PCBA, and the second power circuit may include a third PCBA. The second PCBA and the third PCBA may be arranged adjacent to each other in a first plane, and the first PCBA may arranged in a second plane offset from the first plane by one or more standoffs. In some embodiments, the third PCBA is electrically coupled to the at least one transformer mounted in the enclosure and includes a plurality of layers, and a layer of the plurality of layers includes an EMI shield aligned with the at least one transformer (e.g., of a bridge circuit of a DC-DC converter).

In some embodiments, the at least one transformer includes a primary side and a secondary side, and the second plurality of switching devices includes a first set of switching devices arranged on the primary side of the at least one transformer and a second set of switching devices arranged on the secondary side of the at least one transformer. For example, the second power circuit may include one or more bridge circuits to form a DC-DC converter.

In some embodiments, the system includes an input interface configured to couple the AC system to the AC bus, and also a common mode choke arranged electrically between the input interface and the nanocrystalline filter.

### BRIEF DESCRIPTION OF THE DRAWINGS

The present disclosure, in accordance with one or more various embodiments, is described in detail with reference to the following figures. The drawings are provided for purposes of illustration only and merely depict illustrative embodiments. These drawings are provided to facilitate an understanding of the concepts disclosed herein and shall not be considered limiting of the breadth, scope, or applicability of these concepts. It should be noted that for clarity and ease of illustration these drawings are not necessarily made to scale.

FIG. 1 is a block diagram of an illustrative charger, in accordance with some embodiments of the present disclosure;

FIG. 2 is a schematic diagram of an illustrative charger, in accordance with some embodiments of the present disclosure;

FIG. 3 shows a front view of an illustrative charger without a cover, in accordance with some embodiments of the present disclosure;

FIG. 4 shows a perspective view of a portion of the illustrative charger of

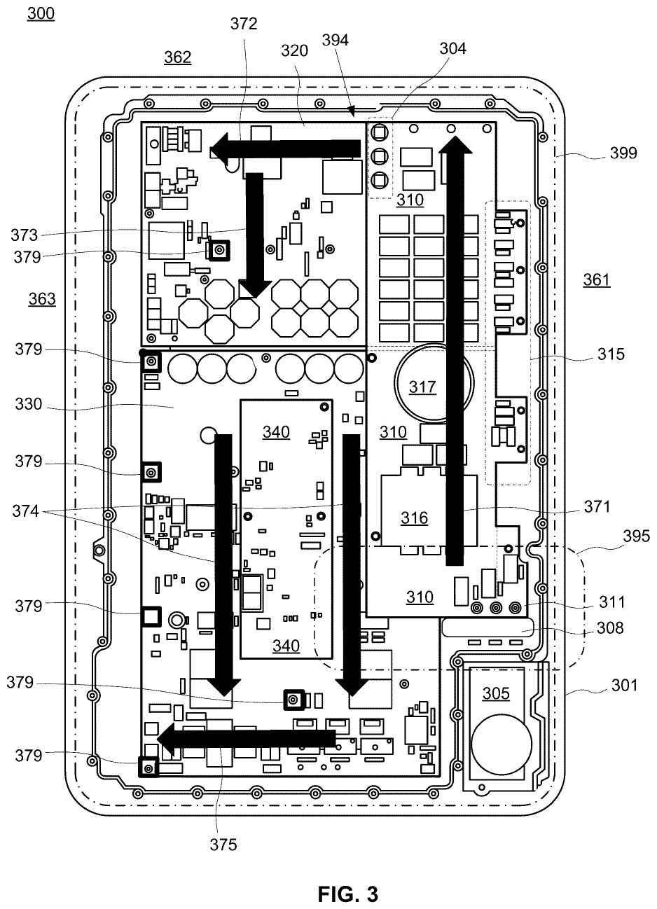

FIG. 3, in accordance with some embodiments of the present disclosure;

FIG. 5 shows a perspective view of another portion of the illustrative charger of

FIG. 3, in accordance with some embodiments of the present disclosure;

FIG. 6A shows a perspective view the illustrative filter system of FIG. 3 configured to condition AC power, in accordance with some embodiments of the present disclosure;

FIG. 6B shows a plan view and a plan view of the illustrative filter system of FIG. 3 configured to condition AC power, unpopulated, in accordance with some embodiments of the present disclosure;

FIG. 7 is a block diagram of an illustrative filter arrangement, in accordance with some embodiments of the present disclosure;

FIG. 8 shows a plan view of the illustrative charger enclosure of FIG. 3, with shielded transformers, in accordance with some embodiments of the present disclosure;

FIG. 9 shows a plan view of an illustrative power circuit PCBA, in accordance with some embodiments of the present disclosure;

FIG. 10 shows a plan view of another illustrative power circuit PCBA, in accordance with some embodiments of the present disclosure;

FIG. 11 is a flowchart of an illustrative process for assembling a charging system, in accordance with some embodiments of the present disclosure; and

FIG. 12 is a flowchart of an illustrative process for managing power flow using a charging system, in accordance with some embodiments of the present disclosure.

### DETAILED DESCRIPTION

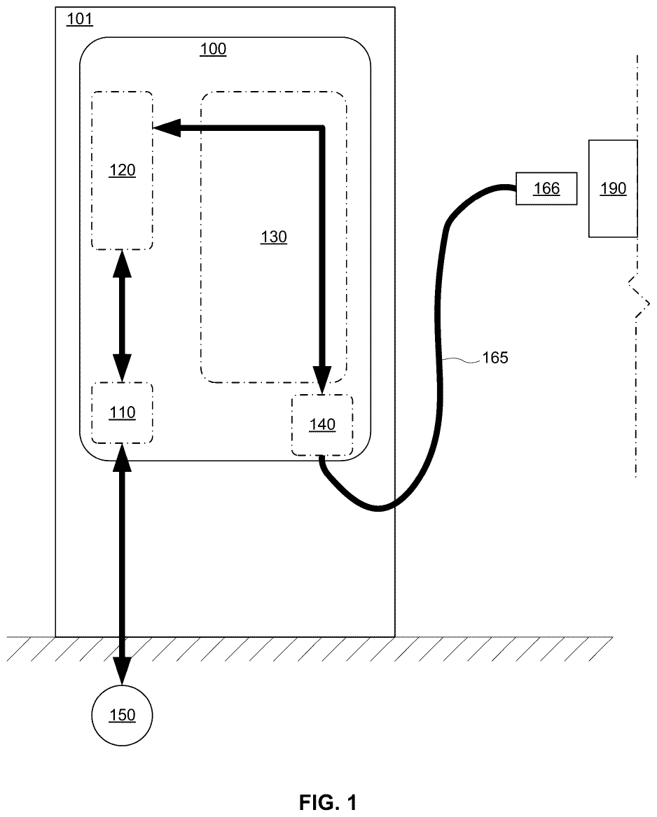

In some embodiments, the present disclosure is directed to an improved layout and packaging arrangement for a charger such as a bi-directional charger for managing power flow between an AC system and an electric vehicle, for example. FIG. 1 is a block diagram of illustrative charger 100, in accordance with some embodiments of the present disclosure. As illustrated, charger 100 is mounted to structure 101 (e.g., a wall, frame, or other structure configured to provide mechanical support) and electrically coupled to AC grid 150 to transfer AC power bi-directionally. In some embodiments, as illustrated, charger 100 includes AC interface 110, converter 120, converter 130, DC interface 140, charging cable 165, and charging connector 166.

In some embodiments, AC interface 110 includes a common-mode choke, an EMI filter, terminals, any other suitable components, or any combination thereof. In some embodiments, converter 120 includes an EMI filter, one or more AC contactors, an AC capacitor bank, switching devices, sensors (e.g., voltage sensors, currents sensors, or both), any other suitable components, or any combination thereof. For example, converter 120 may include circuitry configured to filter AC voltages, modify a power factor of AC voltages, rectify AC voltage to DC voltages, any other suitable actions, or any combination thereof.

In some embodiments, converter 130 includes one or more DC capacitor banks, switching devices (e.g., arranged as one or more bridge circuits), transformers (e.g., coupling two or more bridge circuits), sensors (e.g., voltage sensors, currents sensors, or both), any other suitable components, or any combination thereof. For example, converter 130 may include a dual-active bridge (DAB) or any other suitable DC-DC converter for transferring power between two DC buses, any other suitable actions, or any combination thereof.

In some embodiments, DC interface 140 may include one or more DC contactors, sensors (e.g., voltage sensors, currents sensors, or both), any other suitable components, or any combination thereof. In some embodiments, DC interface is coupled to, or otherwise includes, charging cable 165 and charging connector 166, which may be configured to connect to electric vehicle 190 to provide bi-directional charging.

In an illustrative example, charger 100 may be configured to charge a battery of electric vehicle 190, which may operate in a DC voltage range and state of charge (SOC) range. Charger 100 may be configured to draw power from the battery of electric vehicle 190 and transfer that power to AC grid 150 or another suitable AC system (e.g., a motor, a pump, a circuit, a device, a breaker panel of a house, or any other suitable AC load). Charger 100 may be configured to manage power flow in either direction between AC grid 150 and electric vehicle 190.

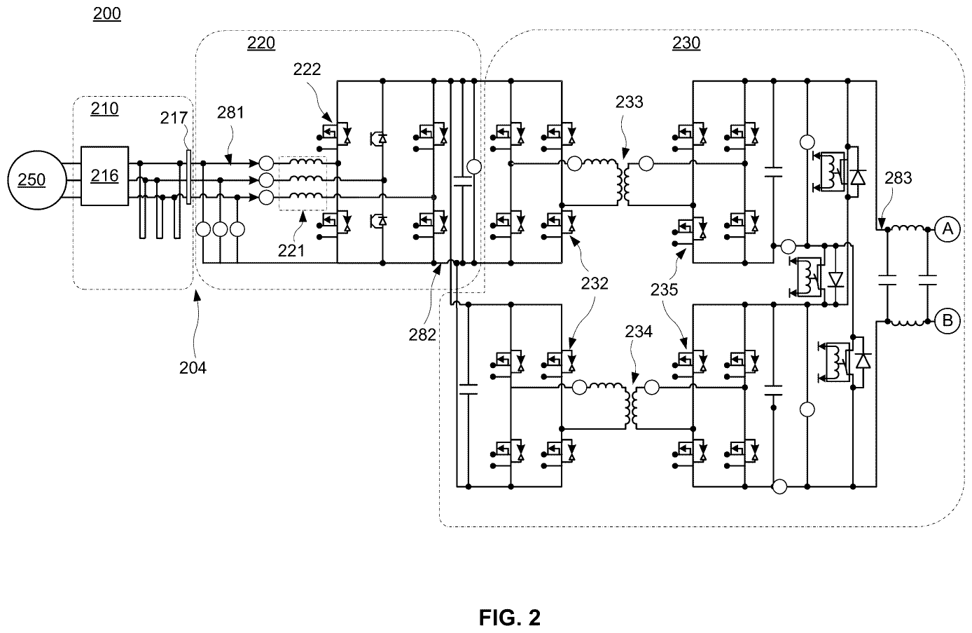

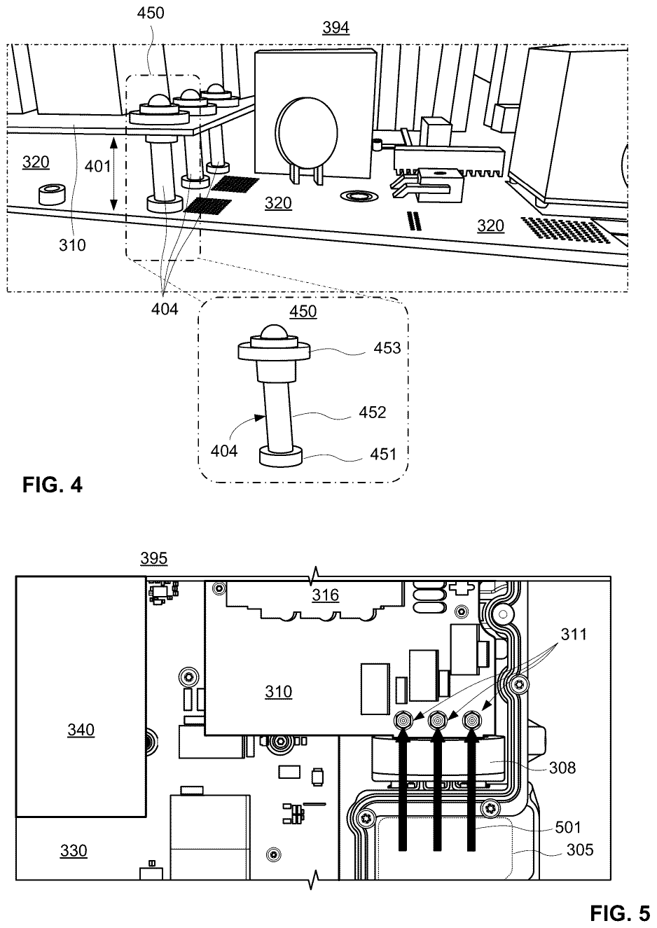

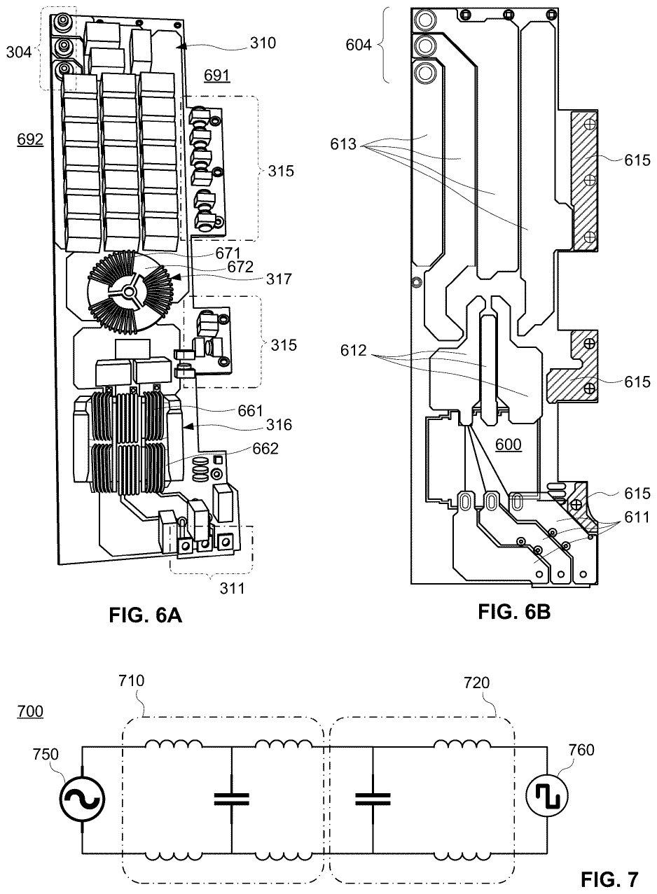

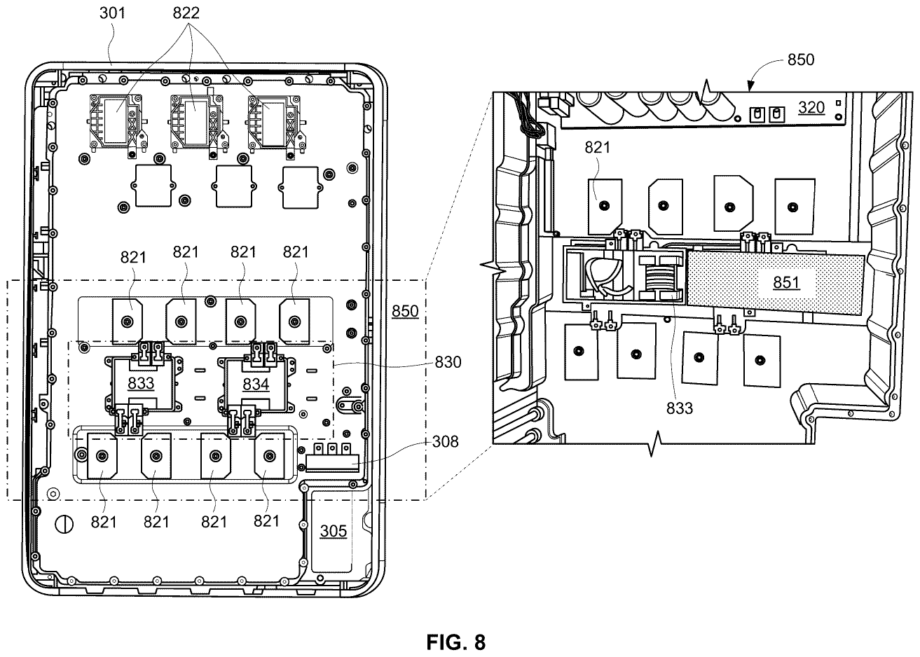

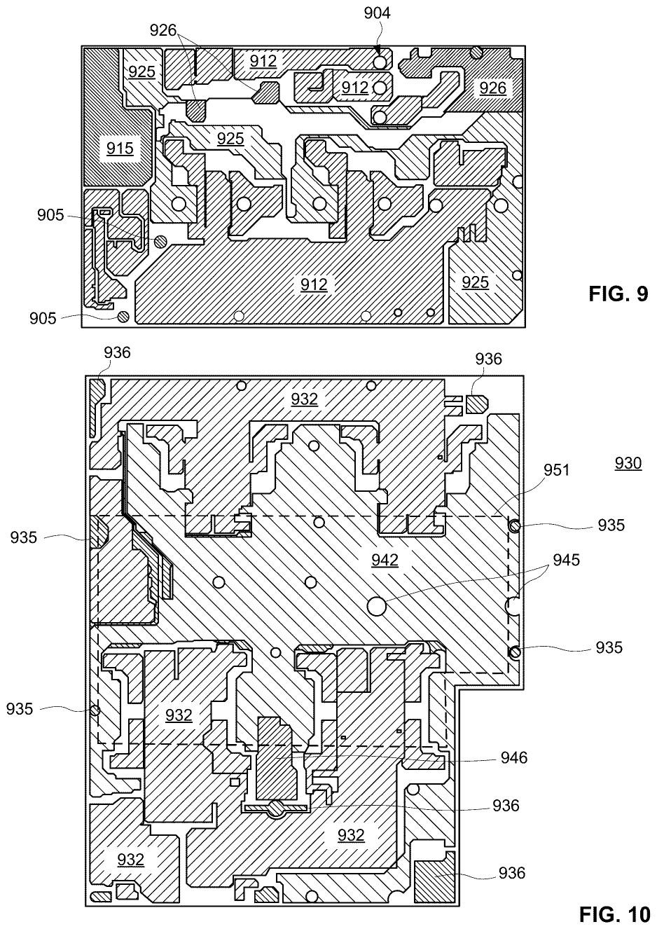

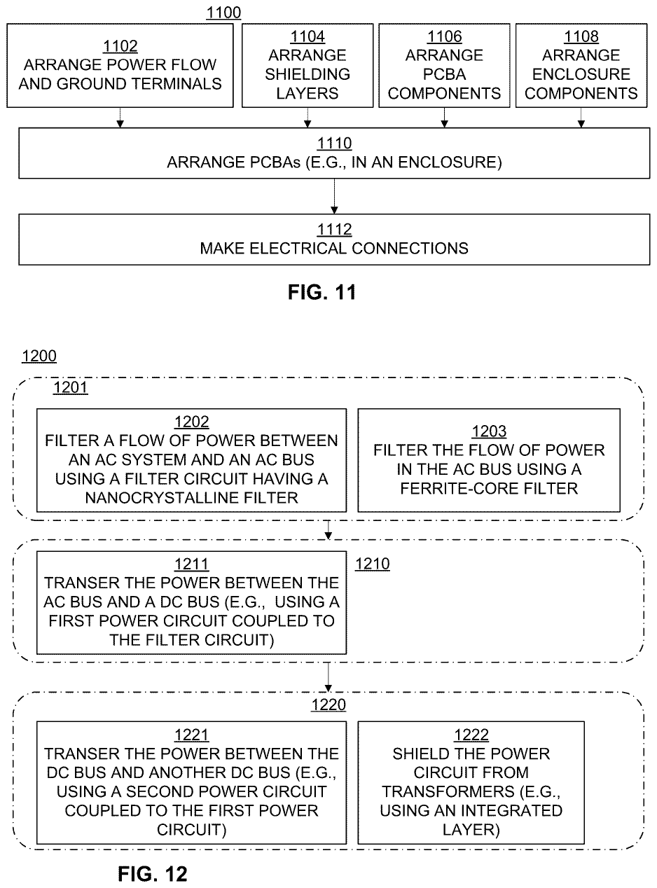

FIG. 2 is a schematic diagram of illustrative charger 200, in accordance with some embodiments of the present disclosure. As illustrated, AC system 250 (e.g., an AC grid) is coupled to filter system 210 configured to condition AC bus 281. As illustrated, first power circuit 220 is configured to transfer power between AC bus 281 and a first DC bus (e.g., DC bus 282). For example, first power circuit 220 may be configured to rectify AC voltage to the first DC bus using plurality of switching devices 222 (e.g., S1-S6 as illustrated). As illustrated, second power circuit 230 is configured to transfer power between the first DC bus and a second DC bus (e.g., DC bus 282 and DC bus 283), which may operate at different nominal DC voltage levels. For example, second power circuit 230 may include a dual-active bridge (DAB) configured to transfer power between DC buses 282 and 283 (e.g., first and second DC buses) using transformers 233 and 234 (e.g., T1 and T2) and pluralities of switching devices 232 and 235 (e.g., Q1-Q16 as illustrated). In an illustrative example, filter system 210 may correspond to AC interface 110 of FIG. 1, first power circuit 220 may correspond to converter 120 of FIG. 1, and second power circuit 230 may correspond to converter 130 of FIG. 1. An illustrative example of interface 204, between filter system 210 and first power circuit 220, is further illustrated in FIG. 4.

The action of plurality of switching devices 222 (e.g., S1-S6) may, for example, introduce EMI into nearby conductors, or even introduce harmonics (e.g., higher frequency character) into AC system 250 connections (e.g., other than a 60 HZ primary frequency). Accordingly, filter system 210 includes EMI filter 216 to help mitigate propagation of EMI. In some embodiments, for example, EMI filter 216 includes a nanocrystalline core to minimize losses (e.g., thus minimizing heat generation). For example, the nanocrystalline structure has high permeability, and high frequency response. If EMI filter 216 were arranged nearer to plurality of switching devices 222, the high frequency content, arising from fast switching (e.g., of SiC-based devices) may cause the filter to suffer relatively large losses (e.g., resulting in relatively more heating and a relatively greater temperature). By arranging one or more filters having ferrite cores (e.g., illustrated by filter 217), or other materials exhibiting lesser frequency response, between EMI filter 216 and the switching devices, losses may be reduced by the filter system. The arrangement and shielding among switching devices, transformers, ground terminals, control connections, sensors, and any other suitable components may be designed to reduce the effects of EMI. For example, first power circuit 220 includes plurality of switching devices 222 configured to convert between AC bus 281 and DC bus 282 (e.g., a first DC bus). In a further example, filter system 210 (e.g., which may include a filter circuit or PCBA) may include a ferrite-core filter (e.g., filter 217) arranged electrically between a nanocrystalline-core filter (e.g., EMI filter 216) and plurality of switching devices 222. The ferrite-core filter may be configured to reduce EMI in AC bus 281 arising from switching of plurality of switching devices 222.

In some embodiments, inductor bank 221 is mounted separately from first power circuit 220. For example, first power circuit 220 may include a PCBA, and inductor bank 221 may be mounted to an enclosure, chassis, or other suitable structure, and electrically coupled to first power circuit 220 via suitable conductors (e.g., terminals, wires, busbars, standoffs, or any suitable combination thereof). Plurality of switching devices 222 may include any suitable type of switching device such as, for example, MOSFETs. In some embodiments, AC bus 281 includes several bus lines (e.g., three as illustrated), which may be switched by plurality of switching devices 222 with suitable phasing to more efficiently convert between AC bus 281 (e.g., shifted 120° in phase for three lines, as illustrated) and DC bus 282 (e.g., a first DC bus). To illustrate, first power circuit 220 may correspond to a bidirectional DC-AC converter. In a further example, first power circuit 220 may correspond to a bidirectional power factor correction (PFC) circuit.

In some embodiments, second power circuit 230 includes bridge circuits arranged on each side of transformers 233 and 234. The bridge circuits include pluralities of switching devices 232 and 235, for example. For example, second power circuit 230 may include a PCBA, and transformers 233 and 234 may be mounted to an enclosure, chassis, or other suitable structure, and electrically coupled to second power circuit 230 via suitable conductors (e.g., terminals, wires, busbars, standoffs, or any suitable combination thereof). Suitable shielding may be arranged between layers of, or otherwise be included as a layer of, the PCBA of second power circuit 230 and transformers 233 and 234. Plurality of switching devices 232 and 235 may include any suitable type of switching device such as, for example, MOSFETs. In some embodiments, as illustrated, each of DC buses 282 and 283 includes two bus lines (e.g., first and second bus lines, which together form the DC bus and operate at a nominal voltage difference). To illustrate, second power circuit 230 may correspond to a dual-active bridge (DAB) circuit. In a further example, first power circuit 220 may correspond to a bidirectional DC-DC converter. In a further example, DC bus 283 (e.g., a first DC bus) may operate at a first nominal voltage, and DC bus 282 (e.g., a second DC bus) may operate at a second nominal voltage greater than the first nominal voltage (e.g., DC bus 282 may correspond to a rectified voltage of AC bus 281, and DC bus 283 may operate at a greater voltage to match a battery system of an electric vehicle). In some embodiments, transformer 233, transformer 234, or both may each include a primary side and a secondary side. For example, the primary side may correspond to plurality of switching devices 232 (e.g., a first plurality or set) and DC bus 282, and the secondary side may correspond to plurality of switching devices 235 (e.g., a second plurality or set) and DC bus 283.

In an illustrative example, markers “A” and “B” in FIG. 2 correspond to bus lines of DC bus 283 (e.g., the voltage difference between the two lines defining the DC bus voltage). In some embodiments, an insulation detection circuit or system, a disconnect system, a voltage sensor, any other suitable component or system, or any combination thereof may be electrically coupled to DC bus 283 to provide power flow to or from an electric vehicle battery. For example, DC interface 140 of FIG. 1 may interface to DC bus 283 wherein DC bus 283 is managed by converter 130.

In a further illustrative example, a charging system may include charger 200, which may include a filter circuit comprising a nanocrystalline filter (e.g., EMI filter 216 of filter system 210) configured to reduce electromagnetic interference (EMI) between an AC bus (e.g., AC bus 281) and an AC system (e.g., AC system 250). The charging system may also include a first power circuit having a plurality of switching devices (e.g., plurality of switching devices 222 of first power circuit 220) and that is configured to transfer power between the AC bus and a first DC bus (e.g., DC bus 282). In some embodiments, the filter circuit is coupled to the first power circuit using one or more terminals with standoffs. The charging system may also include a second power circuit having a plurality of switching devices and at least one transformer (e.g., either or both transformers 233 and 234 of second power circuit 230), and configured to transfer power between the first DC bus and a second DC bus (e.g., DC buses 282 and 283).

In a further illustrative example, a charging system may include charger 200, configured to electrically couple an AC system (e.g., AC grid 150 of FIG. 1, or AC system 250 of FIG. 2) to a battery system of an electric vehicle (e.g., electric vehicle 190 of FIG. 1, via DC interface 140 coupled to DC bus 283 at markers “A” and “B” of FIG. 2). In some embodiments, the charging system includes a high-voltage DC bus (e.g., DC bus 283) that is configured to be coupled to a battery of an electric vehicle (e.g., via DC interface 140). For example, the charging system may include a filter system (e.g., a filter circuit or PCBA, such as filter system 210), and power circuits (e.g., such as first and second power circuits 220 and 230) that are configured to provide bi-directional power transfer between the AC system and the battery of the electrical vehicle.

FIG. 3 shows a plan view of illustrative charger 300 without a cover (e.g., enclosure 301 is uncovered as illustrated), in accordance with some embodiments of the present disclosure. As illustrated, charger 300 includes AC interface 305, filter system 310, power circuit 320, power circuit 330, and controller 340.

AC interface 305 may include, for example, a connection to an AC system. To illustrate, a user may couple charger 300 to an AC system such as a grid by making connections at AC interface 305. AC interface 305 may include an enclosure, terminals, strain reliefs, any other suitable components, or any combination thereof, and may be arranged at a corner of enclosure 301. In some embodiments, as illustrated, AC lines from AC interface 305 pass through common-mode choke 308 to terminals 311 of filter system 310. For example, common-mode choke 308 may include a ferrite core. Region 395 is shown enlarged in FIG. 5. In an illustrative example, a charging system may include an input interface (e.g., AC interface 305) that is configured to couple an AC system (e.g., AC grid 150 of FIG. 1, or AC system 250 of FIG. 2) to an AC bus (e.g., AC bus 281 of FIG. 2), and common-mode choke 308 may be arranged electrically between the input interface and a nanocrystalline-core EMI filter (e.g., EMI filter 316).

Filter system 310, which may include one or more PCBAs, is configured to manage the AC bus. For example, filter system 310 may be configured to reduce EMI from impacting other systems or circuits, lessen EMI propagating to the AC system (e.g., injecting harmonics onto an AC grid), or both. Filter system 310, as illustrated, includes a first filter (e.g., EMI filter 316) and a second EMI filter (e.g., EMI filter 317). In some embodiments, an AC capacitor bank may be arranged between the first and second filters. Filter system 310 may include one or more grounding terminals (e.g., plurality of grounding terminals 315) arranged to reduce EMI. For example, plurality of grounding terminals 315 are arranged along a side of filter system 310, which extends along a side of enclosure 301 (e.g., the right side as illustrated in FIG. 3). In some embodiments, filter system 310 manages a plurality of AC lines, which may be offset in phase from each other. For example, in some embodiments, filter system 310 manages three AC lines shifted in phase from each other by 120°, which may then be coupled to switches of power circuit 320 to convert between AC power and DC power. Filter system 310 is mechanically and electrically coupled to power circuit 320 at interface 304. For example, filter system 310 may be arranged out-of-plane from power circuit 320, offset by a suitable distance. Interface 304 may include standoffs comprising electrical conductors to couple the AC bus to power circuit 320. In some embodiments, interface 304 may include standoffs having electrical conductors, insulation (e.g., arranged around the conductors), pins, fasteners, any other suitable components, or any combination thereof. As illustrated, interface 304 includes three standoffs corresponding to three lines of the AC bus (e.g., shifted in phase from each other by 120°). Interface 304 is shown from direction 394 in FIG. 4.

Power circuit 320 is configured to convert between an AC bus and a DC bus. To illustrate, power circuit 320 may correspond to or otherwise include first power circuit 220 of FIG. 2. For example, power circuit 320 may include a DC-AC converter, having a plurality of switching devices (e.g., plurality of switching devices 222 of FIG. 2). The switching devices may be configured to rectify an AC bus (e.g., AC bus 281 of FIG. 2), invert a DC bus (e.g., DC bus 282 of FIG. 2), or both, to manage power flow in either direction. In some embodiments, power circuit 320 includes, or is otherwise electrically coupled to, an inductor bank (e.g., coupled to the AC bus), one or more sensors (e.g., voltage sensors, current sensors, temperature sensors, or a combination thereof), any other suitable components, or any combination thereof. In some embodiments, power circuit 320 includes one or more PCBAs.

Power circuit 330 is configured to convert between DC buses (e.g., first and second DC buses). To illustrate, power circuit 330 may correspond to or otherwise include second power circuit 230 of FIG. 2. For example, power circuit 330 may include a DC-DC converter, having a plurality of switching devices (e.g., pluralities of switching devices 232 and 235 of FIG. 2). The switching devices may be configured to convert between DC buses (e.g., DC buses 282 and 283 of FIG. 2) operating at different nominal voltages to manage power flow in either direction. In some embodiments, power circuit 330 includes, or is otherwise electrically coupled to, one or more transformers (e.g., coupled between bridges of a primary side and secondary side), one or more sensors (e.g., voltage sensors, current sensors, temperature sensors, or a combination thereof), any other suitable components, or any combination thereof. In some embodiments, power circuit 320 includes one or more PCBAs. In an illustrative example, as illustrated, power circuits 320 and 330 may be arranged in-plane (e.g., or included as regions of a single PCBA), which may be offset from filter system 310 in a direction normal to the plane.

Controller 340 may be configured to control filter system 310, power circuits 320 or 330, or a combination thereof to manage bi-directional power flow. For example, controller 340 may takes one more sensor signals as input, one or more setpoints as input (e.g., such as target values, expected values, nominal values), generate and transmit control signals to suitable terminals (e.g., gates) of switching devices, control opening and closing of contactors, monitor power flow and aspects thereof, any other suitable functions, or any combination thereof. Controller 340 may include one or more PCBAs (e.g., offset out-of-plane with a PCBA of power circuit 330, as illustrated).

As illustrated, power flows 371-375, or collectively a power flow, travel a U-shaped path forming a loop (e.g., an open loop). As used herein, a “loop” may be open, having two sides substantially parallel but having respective current flows in opposite directions. Power flow 371 extends through filter system 310, power flows 372 and 373 extend through power circuit 320, and power flows 374 and 375 extend through power circuit 330 (e.g., to a DC interface). As illustrated, power flows from a filter circuit (e.g., filter system 310) to a first power circuit (e.g., power circuit 320), and from the first power circuit to the second power circuit (e.g., power circuit 330), forming a loop (e.g., as illustrated, an upside-down U-shape, with power flow 371 substantially parallel with and having opposite direction as power flows 373 and 374). Further, ground terminals 379 of the first and second power circuits (e.g., power circuits 320 and 330) are arranged outside of the loop to reduce EMI. In some embodiments, the filter circuit (e.g., filter system 310), the first power circuit (e.g., power circuit 320), and the second power circuit (e.g., power circuit 330) are arranged within a region having a perimeter (e.g., perimeter 399, which bounds an internal area or region). The power flow forms a loop in the region, and ground terminals 379 are arranged between the loop and perimeter 399. To illustrate, a region may include a two-dimensional area, layers that may be two-dimensional themselves but offset from other layers (e.g., within a PCB or among PCBs), three-dimensional arrangements (e.g., a planar dimension and an out-of-plane dimension), or a combination thereof. Further, a perimeter may include a boundary that may be defined in a plane, extend out of plane any suitable distance (e.g., the thickness or depth of an enclosure), follow a contour in three-dimensions, or a combination thereof. To illustrate, perimeter 399 extends around enclosure 301, and charger 300 includes a layered two-dimensional arrangement of PCBAs (e.g., within the thickness of enclosure 301 and any cover, extending in a direction into and out of the page, as illustrated). In some embodiments, perimeter 399 and the corresponding region are defined by enclosure 301, where the filter circuit, the first power circuit, and the second power circuit are arranged inside enclosure 301. In some embodiments, the filter circuit (e.g., filter system 310) is arranged along a first side of the perimeter (e.g., side 361 of perimeter 399 of enclosure 301). In some such embodiments, the first power circuit (e.g., power circuit 320) is arranged along a second side (e.g., side 362) of the perimeter adjacent the first side (e.g., side 361) and behind the filter circuit along the first side. Further, in some such embodiments, the second power circuit (e.g., power circuit 330) is arranged along a third side (e.g., side 363) of perimeter 399, adjacent the first power circuit, and behind the filter circuit, wherein the filter circuit, the first power circuit, and the second power circuit are arranged to reduce differential mode EMI caused by the power flow (e.g., formed by power flows 371-375).

FIG. 4 shows a perspective view of a portion of illustrative charger 300, in accordance with some embodiments of the present disclosure. The portion includes interface 304 as viewed from direction 394 in FIG. 3. As illustrated, filter system 310 is offset by distance 401 from power circuit 320, using interface elements 404. Interface elements 404, as illustrated, include conductor elements that function as structural standoffs, and interface to filter system 310 and power circuit 320. For example, rather than a wire-based connection, interface elements 404 may be used to reduce inductance (e.g., have lesser impedance), and may provide a high-current connector. In a further example, because interface elements 404 exhibit high-frequency response, interface elements 404 help to reduce EMI by reducing impedance. In some embodiments, interface elements 404 are configured as high-power board-to-board connectors. For example, the connectors may each include a socket mounted to a PCBA of filter system 310, where the socket includes a spring-loaded interior (e.g., having a spring configured to apply a radial force) configured to interface to a pin mounted to power circuit 320. As illustrated in enlargement 450 (e.g., of a single interface element), each of interface elements 404 includes mount 451 (e.g., affixed to power circuit 320 and electrically coupled to an AC line), pin 452 (e.g., extending from mount 451 and defining an offset of distance 401), and socket 453 (e.g., affixed to filter system 310 and configured to engage with pin 452 using a spring, press fit, friction interface, or any other suitable connection). Socket 453 may be coupled to an AC line of a DC-AC converter of power circuit 320. Interface elements 404 may, but need not, include electrical insulation around pin 452.

FIG. 5 shows a plan view of another portion of illustrative charger 300 corresponding to region 395, in accordance with some embodiments of the present disclosure. As illustrated, terminals 311 are aligned or nearly aligned with AC interface 305 such that the AC lines need not follow tortuous or elongated paths. For example, because paths 501 (e.g., illustrated as three black arrows) from AC interface 305 to terminals 311 are relatively straight, busbars or additional lengths of conducting material are not needed. By eliminating the need for busbars by aligning terminals 311 of filter system 310 with common-mode choke 308 and AC interface 305, impedance may be improved (e.g., lessened).

FIG. 6A shows a perspective view illustrative filter system 310 of FIG. 3 configured to condition AC power, in accordance with some embodiments of the present disclosure. For example, as illustrated, grounding terminals 315 are arranged to one side (e.g., side 691) of filter system 310, and not in-line with EMI filters 316 and 317, or other components (e.g., not along the path of the main power flow). FIG. 6B shows a plan view of illustrative filter system 310, unpopulated, in accordance with some embodiments of the present disclosure. As illustrated in FIG. 6B, PCBA 600 shows grounding layer 615 as not overlapping AC layers 612 and 613 or input interface layers 611. Accordingly, the power flow through filter system 310 and grounds are separated on the PCBA. For example, filter system 310 does not include ground connections to power circuits 320 and 330 arranged underneath filter system 310 (e.g., offset underneath by interface elements 404). In a further example, filter system 310 may include mounting points on side 692 or arranged throughout PCBA 600, but no ground connections are arranged other than along side 691. As illustrated, EMI filter 316 includes windings 661 around core 662 (e.g., a nanocrystalline core material or any other suitable material having high-frequency response), and EMI filter 317 includes windings 671 around core 672 (e.g., a ferrite core or any other suitable material).

FIG. 7 is a block diagram of illustrative filter arrangement 700, in accordance with some embodiments of the present disclosure. As illustrated, filter arrangement 700 includes filter 710 and filter 720 arranged between AC system 750 (e.g., an AC grid) and AC stage 760, which may correspond to a DC-AC converter (e.g., such as first power circuit 220 of FIG. 2 or power circuit 320 of FIG. 3). For example, because the voltage character of AC system 750 may be substantially sinusoidal, and the voltage character of AC stage 760 may include additional harmonics due to high frequency switching events, filters 710 and 720 help to reduce distortions or harmonics propagating to AC system 750. In a further example, each of filter 710 and filter 720 may exhibit a frequency response, and incur losses based on the behavior of the AC bus.

Filter 710, which is illustrated as being arranged nearer AC system 750, may include an inductor made of a material having higher permeability material (e.g., and higher frequency response). To illustrate, filter 710 may include wire wound around a core made of a nanocrystalline material. Filter 720 is illustrated as being arranged nearer AC stage 760, and may include wire wound around a core of material having relatively lower permeability (e.g., such a ferrite core). The arrangement allows filter arrangement 700 to optimize or otherwise lessen core loss (e.g., and heat generation) and improve EMI performance. In an illustrative example, filter 710 may correspond to EMI filter 316 of FIG. 3, and filter 720 may correspond to EMI filter 317 of FIG. 3. In a further illustrative example, filter 710 may include a maximum impedance at a frequency of an order of magnitude greater than (e.g., about 10×) a frequency where the impedance of filter 720 reaches a maximum value. In a further illustrative example, filter 710 may include a maximum impedance around 10 kHz, while filter 720 may include a maximum impedance around 1 kHz.

FIG. 8 shows a plan view of illustrative enclosure 301 of FIG. 3, with shielded transformers, in accordance with some embodiments of the present disclosure. Panel 850 illustrates part of enclosure 301, with power circuit 320 and transformers 833 and 834 installed (e.g., although transformer 834 is not visible behind shield 851). Thermal interface pads 821 are illustrated in FIG. 8, and are configured to interface to switching devices to provide heat transfer (e.g., such that enclosure 301 acts as a heat sink). In some embodiments, components such as AC inductors 822 and transformers 833 and 834 may be mounted to enclosure 301 rather than directly to a PCBA, and coupled via wires or other suitable electrical conductors. For example, AC inductors 822, which may be the same as, or otherwise part of, inductor bank 221 of FIG. 2, may be arranged outside of the loop formed by the power flow (e.g., outside of power flow 372 of FIG. 3 and nearer to perimeter 399).

In some embodiments, a PCBA includes an integrated shield as part of a layer of the PCBA that is arranged directly over transformers of a DC-DC converter, when installed. For example, referencing FIG. 3, power circuit 330 (e.g., a multi-layer PCBA) may include the shield layer integrated into a bottom layer and arranged over transformers of the DC-DC converter (e.g., transformers 233 and 234 of FIG. 2, or transformers 833 and 834 of FIG. 8). As illustrated, transformers 833 and 834 are mounted to enclosure 301, and power circuits 320 and 330 would then be mounted to enclosure 301, arranged over transformers 833 and 834, and then filter system 310 would be installed above power circuits 320 and 330 (e.g., offset using interface elements 404 of FIG. 4). Because each of transformers 833 and 834 include windings (e.g., primary and secondary) and cores and power circuit 330 includes a plurality of switching devices (e.g., of bridge circuit including pluralities of switching devices 232 and 235 arranged electrically on either side of each of transformer 833 and 834), shielding may help reduce EMI in region 830. For example, each of transformers 833 and 834 may include a primary side and a secondary side, and power circuit 330 may include a first plurality of switching devices arranged on the primary side and a second plurality of switching devices arranged on the secondary side (e.g., corresponding to pluralities of switching devices 232 and 235 of FIG. 2).

In some embodiments, one or more shields may be mounted to enclosure 301 between transformers 833 and 834, one of which is illustrated in panel 850 by shield 851 (e.g., an electrically conductive plate, as illustrated) arranged to cover transformer 834. In some embodiments, where one or more transformers are mounted in an enclosure, a separate shield plate need not be included, and one or more PCBAs may include an integrated shielding layer. For example, by omitting a separate shield, the spacing may be reduced (e.g., tighter packaging) because fasteners and additional shield materials are not needed. The shielding layer may include a layer of a PCB having electrically conducting material covering a region and being electrically terminated (e.g., to ground or suitable reference). FIG. 10 illustrates a PCBA having an integrated shielding layer, for example.

FIG. 9 shows a plan view of illustrative PCBA 920 corresponding to a power circuit, in accordance with some embodiments of the present disclosure. For example, PCBA 920 may correspond to power circuit 320 of FIG. 3, or otherwise a portion thereof. As illustrated, PCBA 920 includes interface 904, ground terminations 905, high-voltage layer 912, ground layer 915, low-voltage control layer 925, and signal layer 926 (e.g., for analog-to-digital conversion of sensor signals). By arranging the layout of PCBA 920, including the positioning of layers, ground terminations, and interfaces to other boards, EMI may be managed (e.g., reduced). For example, separating high-voltage layer 912 from low-voltage control layer 925, signal layer 926, and ground layer 915 may help define and utilize the power flow of the charger. For example, ground terminations 905 and ground layer 915 are arranged outside of the power flow (e.g., formed by power flows 371-374 in FIG. 3) to avoid or otherwise reduce EMI. In a further example, the power layer (e.g., high-voltage layer 912) is separated from an ADC reference plane (e.g., signal layer 926). In a further example, PCBA 920 may include adding grounding points (e.g., ground terminations 905) on a high-voltage side (e.g., high-voltage layer 912) to couple to high-frequency capacitors (e.g., connected to ground) to improve a common mode path for one or more flyback supplies (e.g., of a DC-AC converter of power circuit 320). For example, the high-frequency capacitors may help to minimize or otherwise reduce EMI by providing a nearby ground to minimize noise (e.g., to avoid or reduce EMI of nearby components such as power supplies).

FIG. 10 shows a plan view of illustrative PCBA 930 corresponding to another power circuit, in accordance with some embodiments of the present disclosure. For example, PCBA 930 may correspond to power circuit 330 of FIG. 3, or otherwise a portion thereof. As illustrated, PCBA 930 includes high-voltage layer 932, shielding terminations 935, high-frequency capacitors 936 connecting to ground, layer 942, and supports 945. PCBA 930 also includes shielding layer 951 arranged at a lower layer (e.g., rendered as a dashed line) behind the illustrated layers. For example, PCBA 930 may include a shielding layer that includes a conductive material. To illustrate, a PCBA may have N layers, and the shielding layer may be arranged in one of the N layers (e.g., shielding layer 951 may be the sixth layer of a six-layer PCB). In a further example, shielding layer 951 may be configured to be arranged over or otherwise overlapping transformers (e.g., transformers 233 and 234 of FIG. 2, or transformers 833 and 834 of FIG. 8). In a further example, PCBA 930 may include a plurality of layers, and one layer of the plurality of layers includes an EMI shield aligned with at least one transformer electrically coupled to PCBA 930.

In some embodiments, shielding layer 951 is grounded via shielding terminations 935, which are arranged outside of the loop of power flow (e.g., near the edges or perimeter 399 of FIG. 3). In some embodiments, PCBA 930 need not include a shielding layer, and a separate EMI shield may be arranged between the PCBA and one or more transformers. As illustrated, PCBA 930 includes high-frequency capacitors 936 coupled to ground, as well as high-frequency capacitors arranged at DC terminals of each leg of the bridge circuits of power circuit 330 (e.g., high-frequency capacitors arranged at each input and output of the bridge circuits). Similar to PCBA 920, PCBA 930 includes a separated power plane (e.g., high-voltage layer 932) and reference plane (e.g., ADC reference layer 946). In some embodiments, the layout of PCBA 930 minimizes or otherwise reduces switching loop inductance. In some embodiments, supports 945 are included to support a filter system (e.g., filter system 310 of FIG. 3) that may be offset from PCBA 930 by a distance (e.g., lying in a parallel and offset plane). For example, supports 945 may be configured to provide structural support but do not include ground connections to prevent coupling EMI between PCBA 930 and the filter system.

FIG. 11 is a flowchart of illustrative process 1100 for assembling a charging system, in accordance with some embodiments of the present disclosure.

Step 1102 includes arranging a power flow and ground terminals of the charging system. In some embodiments, step 1102 includes arranging the power flow in a U-shape to form a loop, to help reduce differential mode EMI. In some embodiments, step 1102 includes arranging a plurality of grounding terminals outside of the loop to help reduce EMI.

Step 1104 includes arranging shielding layers. In some embodiments, one or more shielding layers may be formed as a layer of a PCBA such that additional fasteners or hardware may be omitted (e.g., as compared to installing a separate shield that is not integrated as part of a PCBA). In some embodiments, one or more shields may be installed to shield one or more transformers (e.g., of a DC-DC converter).

Step 1106 includes arranging PCBA components. In some embodiments, step 1106 includes placing components at locations on each PCB (e.g., where pins of the components line up with either surface-mount terminals or through-hole terminals connected by conductive traces). In some embodiments, step 1106 includes applying flux, solder, or both to affix the components to the PCB. The components may include integrated chips or other suitable chips, circuit elements (e.g., resistors, capacitors, inductors, switches, diodes, transistors, LEDs, batteries), terminal blocks or connectors, any other suitable components, or any combination thereof.

Step 1108 includes arranging enclosure components (e.g., of enclosure 301 of FIG. 3). In some embodiments, step 1108 includes arranging one or more parts of an enclosure, brackets, seals, fasteners, thermal interface materials, mounting hardware, grounding connections, any other suitable components, or any combination thereof. For example, in some embodiments, step 1108 includes preparing one or more enclosure elements to receive one or more PCBAs.

Step 1110 includes arranging one or more PCBAs. In some embodiments, the charging system may include one or more PCBAs, which may be arranged in the enclosure and relative to each other at locations in-plane, out-of-plane (e.g., offset), or a combination thereof. For example, as illustrated in FIG. 3, one or more PCBAs may be arranged in the same plane (e.g., power circuits 320 and 330) with one or more PCBAs offset at one or more other planes (e.g., filter system 310 and controller 340).

Step 1112 includes making electrical connections. In some embodiments, once the PCBAs are installed, electrical connections among the PCBAs, transformers, inductor banks, grounding terminals, AC interface, DC interfaces, connectors, any other suitable components or subsystems of the charging system, or any combination thereof.

FIG. 12 is a flowchart of illustrative process 1200 for managing power flow using a charging system, in accordance with some embodiments of the present disclosure.

Process 1201 includes filtering the flow of power. Step 1202 includes filtering a flow of power between an AC system and an AC bus, using at least one filter circuit having a nanocrystalline filter (e.g., a wound filter with a core of a nanocrystalline material). Step 1203 includes filtering the flow of power in the AC bus using a ferrite-core filter. For example, the ferrite-core filter may be arranged between the nanocrystalline filter and a DC-AC converter having a plurality of switching devices such as MOSFETs (e.g., plurality of switching devices 222 of FIG. 2).

Process 1210 includes transferring the power using a DC-AC converter. Step 1211 includes, for example, transferring the power between the AC bus and a DC bus using an inductor bank (e.g., inductor bank 221 of FIG. 2), a plurality of switching devices (e.g., plurality of switching devices 222 of FIG. 2), any other suitable components, or any combination thereof.

Process 1220 includes transferring the power using a DC-DC converter. Step 1221 includes transferring the power between the DC bus and another DC bus (e.g., using a second power circuit) using one or more transformers each having a primary side and a secondary side (e.g., transformers 233 and 234 of FIG. 2, or transformers 833 and 834 of FIG. 8), a plurality of switching devices arranged on the primary side and second side of the one or more transformers (e.g., pluralities of switching devices 232 and 235 of FIG. 2), capacitors, any other suitable components, or any combination thereof. Step 1222 includes shielding the power circuit (e.g., second power circuit 230 of FIG. 2, power circuit 330 of FIG. 3) from the one or more transformers (e.g., transformers 233 and 234 of FIG. 2, or transformers 833 and 834 of FIG. 8). In some embodiments, step 1222 includes using a shield, which may be integrated as part of a PCBA (e.g., as a layer of conducting material), a separate component that is mounted to the enclosure, any other suitable shield type, or any combination thereof.

The foregoing is merely illustrative of the principles of this disclosure and various modifications may be made by those skilled in the art without departing from the scope of this disclosure. The above-described embodiments are presented for purposes of illustration and not of limitation. The present disclosure also can take many forms other than those explicitly described herein. Accordingly, it is emphasized that this disclosure is not limited to the explicitly disclosed methods, systems, and apparatuses, but is intended to include variations to and modifications thereof, which are within the spirit of the following claims.

What is claimed is:

1. A system comprising:
a filter circuit comprising a nanocrystalline filter configured to reduce electromagnetic interference (EMI) between an AC bus and an AC system;
a first power circuit comprising a first plurality of switching devices and configured to transfer power between the AC bus and a first DC bus, wherein the filter circuit is coupled to the first power circuit using one or more terminals with standoffs; and
a second power circuit comprising a second plurality of switching devices and coupled to at least one transformer, and configured to transfer power between the first DC bus and a second DC bus.

2. The system of claim 1, wherein:
a power flow from the filter circuit to the first power circuit, and from the first power circuit to the second power circuit forms a loop;
the first and second power circuits comprise a plurality of ground terminals; and
the plurality of ground terminals are arranged outside of the loop.

3. The system of claim 2, wherein:
the filter circuit, the first power circuit, and the second power circuit are arranged within a region having a perimeter;
the power flow forms a loop in the region; and
the plurality of ground terminals are arranged between the loop and the perimeter.

4. The system of claim 3, further comprising an enclosure defining the perimeter, wherein the filter circuit, the first power circuit, and the second power circuit are arranged inside the enclosure.

5. The system of claim 3, wherein:
the filter circuit is arranged along a first side of the perimeter;
the first power circuit is arranged along a second side of the perimeter adjacent the first side and behind the filter circuit along the first side; and
the second power circuit is arranged along a third side of the perimeter, adjacent the first power circuit, and behind the filter circuit, wherein the filter circuit, the first power circuit, and the second power circuit are arranged to reduce differential mode EMI caused by the power flow.

6. The system of claim 1, wherein:
the first power circuit comprises a plurality of switches configured to convert between the AC bus and the first DC bus; and
the filter circuit comprises a ferrite filter arranged electrically between the nanocrystalline filter and the plurality of switches of the first power circuit and configured to reduce EMI in the AC bus arising from switching of the plurality of switches.

7. The system of claim 1, wherein the second power circuit comprises:
a printed circuit board assembly comprising a plurality of layers; and
a layer of the plurality of layers comprises an EMI shield aligned with the at least one transformer electrically coupled to the second power circuit.

8. The system of claim 7, wherein:
the at least one transformer comprises a primary side and a secondary side; and
the second plurality of switching devices comprises a first set of switching devices arranged on the primary side of the at least one transformer and a second set of switching devices arranged on the secondary side of the at least one transformer.

9. The system of claim 1, wherein:
the first DC bus operates at a first nominal voltage; and
the second DC bus operates at a second nominal voltage greater than the first nominal voltage.

10. The system of claim 1, wherein:
the second DC bus is configured to be coupled to a battery of an electric vehicle; and
the filter circuit, the first power circuit, and the second power circuit are configured to provide bi-directional power transfer between the AC system and the battery of the electrical vehicle.

11. The system of claim 1, further comprising:
an input interface configured to couple the AC system to the AC bus; and
a common mode choke arranged electrically between the input interface and the nanocrystalline filter.

12. An electric charger system comprising:
an enclosure;
a filter circuit arranged in the enclosure and comprising a nanocrystalline filter configured to reduce electromagnetic interference (EMI) between an AC bus and an AC system;
a first power circuit arranged in the enclosure and comprising a first plurality of switching devices and configured to transfer power between the AC bus and a first DC bus, wherein the filter circuit is coupled to the first power circuit using one or more terminals with standoffs; and
a second power circuit arranged in the enclosure and comprising a second plurality of switching devices and coupled to at least one transformer, and configured to transfer power between the first DC bus and a second DC bus.

13. The electric charger system of claim 12, wherein:
the enclosure defines a region and a perimeter;
a power flow from the filter circuit to the first power circuit, and from the first power circuit to the second power circuit forms a loop in the region;
the first and second power circuits comprise a plurality of ground terminals; and
the plurality of ground terminals are arranged outside of the loop and within the perimeter.

14. The electric charger system of claim 12, wherein:
the first power circuit comprises a plurality of switches configured to convert between the AC bus and the first DC bus; and
the filter circuit comprises a ferrite filter arranged electrically between the nanocrystalline filter and the plurality of switches of the first power circuit and configured to reduce EMI in the AC bus arising from switching of the plurality of switches.

15. The electric charger system of claim 12, wherein the second power circuit comprises:
a printed circuit board assembly comprising a plurality of layers; and
a layer of the plurality of layers comprises an EMI shield aligned with the at least one transformer mounted to the enclosure.

16. The electric charger system of claim 12, wherein:
the second DC bus is configured to be coupled to a battery of an electric vehicle; and
the filter circuit, the first power circuit, and the second power circuit are configured to provide bi-directional power transfer between the AC system and the battery of the electrical vehicle.

17. The electric charger system of claim 12, further comprising:
an input interface configured to couple the AC system to the AC bus; and
a common mode choke arranged electrically between the input interface and the nanocrystalline filter.

18. A system comprising:
an enclosure;
a first printed circuit board assembly (PCBA) arranged in the enclosure and comprising a nanocrystalline filter configured to reduce electromagnetic interference (EMI) between an AC bus and an AC system;
a second PCBA arranged in the enclosure and comprising a first plurality of switching devices and configured to transfer power between the AC bus and a first DC bus, wherein the second PCBA is coupled to the first PCBA using one or more terminals with standoffs; and
a third PCBA arranged in the enclosure and comprising a second plurality of switching devices and coupled to at least one transformer, and configured to transfer power between the first DC bus and a second DC bus.

19. The system of claim 18, wherein:
the second PCBA and the third PCBA are arranged adjacent to each other in a first plane; and
the first PCBA is arranged in a second plane offset from the first plane by the one or more terminals with standoffs.

20. The system of claim 18, wherein:
the third PCBA is electrically coupled to the at least one transformer mounted in the enclosure;
the third PCBA comprises a plurality of layers; and
a layer of the plurality of layers comprises an EMI shield aligned with the at least one transformer.
